(19) United States
(12) Patent Application Publication
(10) Pub. No.: US 2025/0022817 A1
(43) Pub. Date: Jan. 16, 2025

(54) HIGH-FREQUENCY MODULE

(71) Applicant: Murata Manufacturing Co., Ltd., Kyoto (JP)

(72) Inventor: Tetsurou ASHIDA, Kyoto (JP)

(21) Appl. No.: 18/898,846

(22) Filed: Sep. 27, 2024

Related U.S. Application Data
(63) Continuation of application No. PCT/JP2023/012690, filed on Mar. 28, 2023.

(30) Foreign Application Priority Data
Mar. 30, 2022 (JP) 2022-057359

(51) Int. Cl. H01L 23/66; H01L 23/00; H01L 23/13; H01L 23/498; H01L 25/16; H05K 1/18

(52) U.S. Cl. CPC H01L 23/66; H01L 23/13; H01L 23/49827; H01L 24/16; H01L 24/13; H01L 25/16; H01L 2223/6644; H01L 2223/6672; H01L 2224/13144; H01L 2224/13147; H01L 2224/16225; H01L 2924/1421; H01L 2924/15151; H05K 1/181

(57) ABSTRACT

A high-frequency module includes a substrate having a first main surface and a second main surface facing each other and a through-hole that extends through the substrate from the first main surface to the second main surface, a first electronic component, and a second electronic component, and the second electronic component is disposed inside the through-hole of the substrate, the first electronic component is disposed so as to extend over the first main surface of the substrate and the second electronic component, the first electronic component is connected to the first main surface of the substrate with a first connection member interposed therebetween, the second electronic component is connected to the first electronic component with a second connection member interposed therebetween, and a first direct current signal is supplied to the second electronic component through the first connection member, the first electronic component, and the second connection member.

### CROSS REFERENCE TO RELATED APPLICATION

This is a continuation of International Application No. PCT/JP2023/012690 filed on Mar. 28, 2023 which claims priority from Japanese Patent Application No. 2022-057359 filed on Mar. 30, 2022. The contents of these applications are incorporated herein by reference in their entireties.

### BACKGROUND OF THE DISCLOSURE

### Field of the Disclosure

The present disclosure relates to a high-frequency module.

### Description of the Related Art

The integrated circuit (IC) module described in Patent Document 1 includes a substrate and a plurality of IC chips mounted on the substrate. The plurality of IC chips is arranged side by side on the same plane of the substrate.
Patent Document 1: Japanese Unexamined Patent Application Publication No. 2002-343926

### BRIEF SUMMARY OF THE DISCLOSURE

In the IC module described in Patent Document 1, reduction in size may become difficult in a plane direction.

A possible benefit of the present disclosure is to provide a high-frequency module capable of achieving reduction in size in a plane direction.

One aspect of the present disclosure is a high-frequency module including a substrate having a first main surface and a second main surface facing each other and a through-hole that extends through the substrate from the first main surface to the second main surface, a first electronic component, and a second electronic component, in which the second electronic component is disposed inside the through-hole of the substrate, the first electronic component is disposed to extend over the first main surface of the substrate and the second electronic component, the first electronic component is connected to the first main surface of the substrate with a first connection member interposed therebetween, the second electronic component is connected to the first electronic component with a second connection member interposed therebetween, and a first direct current signal is supplied to the second electronic component through the first connection member, the first electronic component, and the second connection member.

According to the high-frequency module of the present disclosure, reduction in size in a plane direction can be achieved.

### BRIEF DESCRIPTION OF THE SEVERAL VIEWS OF THE DRAWINGS

FIG. 1 is a plan view schematically illustrating a configuration of a high-frequency module according to a first embodiment.

FIG. 2 is a sectional view taken along line II-II′ of FIG. 1.

FIG. 3 is a sectional view schematically illustrating a configuration of a high-frequency module according to a first modification of the first embodiment.

FIG. 4 is a plan view schematically illustrating a configuration of a high-frequency module according to a second embodiment.

FIG. 5 is a sectional view taken along line V-V′ of FIG. 4.

FIG. 6 is a sectional view schematically illustrating a configuration of a high-frequency module according to a third embodiment.

FIG. 7 is a sectional view schematically illustrating a configuration of a high-frequency module according to a second modification of the third embodiment.

### DETAILED DESCRIPTION OF THE DISCLOSURE

Hereinafter, embodiments of a high-frequency module of the present disclosure will be described in detail based on the drawings. Note that the present disclosure is not limited by the embodiments. Obviously, each embodiment is illustrative, and configurations described in different embodiments are able to be partially replaced or combined with each other. In embodiments after the second embodiment, description of matters common to the first embodiment will be omitted, and only different points will be described. In particular, the same operational effects achieved by the same configuration will not be described one by one for each embodiment.

### First Embodiment

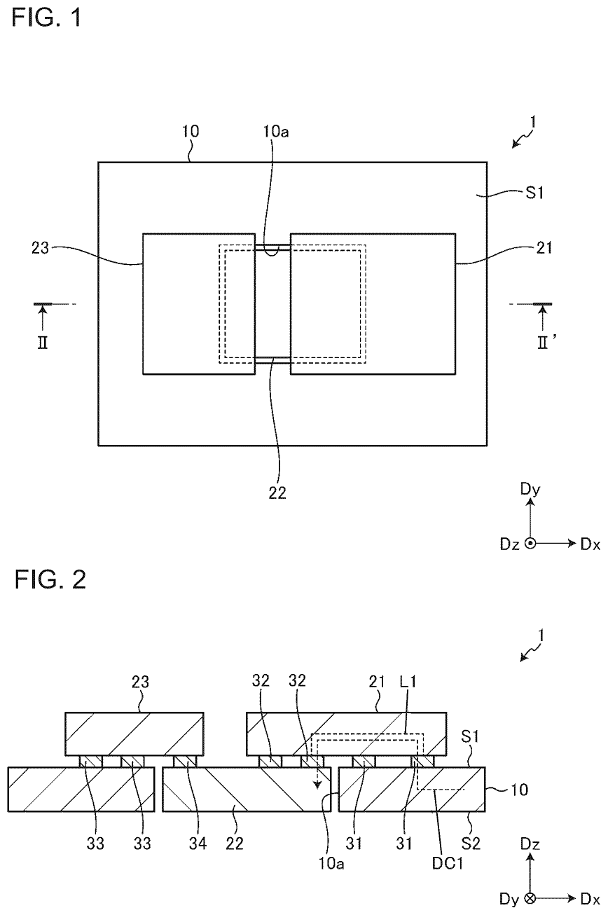

FIG. 1 is a plan view schematically illustrating a configuration of a high-frequency module according to a first embodiment. FIG. 2 is a sectional view taken along line II-II′ of FIG. 1. As illustrated in FIGS. 1 and 2, the high-frequency module 1 according to the first embodiment includes a substrate 10, a first electronic component 21, a second electronic component 22, a third electronic component 23, and connection members 31, 32, 33, and 34.

As illustrated in FIG. 1, the substrate 10 has a rectangular outer shape in plan view and is provided with a through-hole 10a having a rectangular shape in a central portion. As illustrated in FIG. 2, the substrate 10 is a plate-like insulating substrate having a first main surface S1 and a second main surface S2 facing each other. The second main surface S2 is a surface on a side opposite to the first main surface S1 side. In addition, the through-hole 10a extends through the substrate 10 from the first main surface S1 to the second main surface S2 in a thickness direction of the substrate 10.

The substrate 10 may be a multilayer substrate including a plurality of insulating layers. Although not illustrated, the first main surface S1 of the substrate 10 is provided with an electrode or a wiring pattern electrically coupled to the connection members 31 and 33. In addition, an inner layer of the substrate 10 is also provided with a via connecting various wiring patterns and layers. The substrate 10 is, for example, a printed circuit board of glass epoxy or the like, a ceramic substrate such as an alumina substrate, a flexible substrate of polyimide or the like, or a liquid crystal polymer substrate. Note that the substrate 10 is not limited to a multilayer substrate and may be a single-layer substrate.

Note that in the following description, a direction in a plane parallel to a plane of the substrate 10 including the first main surface S1 is referred to as a first direction Dx. A direction orthogonal to the first direction Dx in the plane parallel to the plane including the first main surface S1 is referred to as a second direction Dy. In addition, a direction orthogonal to each of the first direction Dx and the second direction Dy is referred to as a third direction Dz. The third direction Dz is a normal direction of the first main surface S1. In addition, in the specification, a plan view indicates a positional relation when viewed in the third direction Dz.

The first electronic component 21, the second electronic component 22, and the third electronic component 23 are active components. Specifically, the first electronic component 21 and the third electronic component 23 are power amplifiers, and the second electronic component 22 is a control circuit that controls the operation of the first electronic component 21 and the third electronic component 23. The first electronic component 21, the second electronic component 22, and the third electronic component 23 are configured as integrated circuit (IC) chips.

As illustrated in FIG. 1, the second electronic component 22 is disposed inside the through-hole 10a of the substrate 10. The first electronic component 21 is disposed so as to extend over the first main surface S1 of the substrate 10 and the second electronic component 22. In other words, the first electronic component 21 has a portion overlapping with the second electronic component 22 and a portion overlapping with the first main surface S1 of the substrate 10 in plan view.

The third electronic component 23 is disposed so as to be adjacent to the first electronic component 21 with a space interposed therebetween in the first direction Dx. The third electronic component 23 is disposed so as to extend over the first main surface S1 of the substrate 10 and the second electronic component 22. In other words, the third electronic component 23 has a portion overlapping with the second electronic component 22 and a portion overlapping with the first main surface S1 of the substrate 10 in plan view. A part of the second electronic component 22 is disposed between the first electronic component 21 and the third electronic component 23 in the first direction Dx.

As illustrated in FIG. 2, the first electronic component 21 is connected to the first main surface S1 of the substrate 10 with the connection member 31 (a first connection member) interposed therebetween. The connection member 31 is disposed between the first main surface S1 of the substrate 10 and the first electronic component 21. In addition, the second electronic component 22 is connected to the first electronic component 21 with the connection member 32 (a second connection member) interposed therebetween. The connection member 32 is disposed between the second electronic component 22 and the first electronic component 21. The first electronic component 21 is provided with a signal path L1 connecting the connection member 31 and the connection member 32. Note that in FIG. 2, only one signal path L1 is illustrated to facilitate visualization, but a plurality of the signal paths L1 may be formed in the first electronic component 21.

With such a configuration, the second electronic component 22 disposed inside the through-hole 10a of the substrate 10 is electrically coupled to a wiring pattern provided on the substrate 10 through the connection member 32, the first electronic component 21, and the connection member 31. A first direct current signal DC1 is supplied to the second electronic component 22 from the substrate 10 through the connection member 31 (the first connection member), the signal path L1 of the first electronic component 21, and the connection member 32 (the second connection member).

For example, the first direct current signal DC1 is a ground signal. Alternatively, the first direct current signal DC1 may be a control signal, a power signal, or the like of the second electronic component 22. The first direct current signal DC1 is a signal supplied from a power supply circuit included in an external electronic device or an external host IC.

Similarly, the third electronic component 23 is connected to the first main surface S1 of the substrate 10 with the connection member 33 (a third connection member) interposed therebetween. The connection member 33 is disposed between the first main surface S1 of the substrate 10 and the third electronic component 23. In addition, the second electronic component 22 is connected to the third electronic component 23 with the connection member 34 (a fourth connection member) interposed therebetween. The connection member 34 is disposed between the second electronic component 22 and the third electronic component 23. The connection members 31, 32, 33, and 34 are composed of a bump or a solder formed of a conductive material such as gold (Au) or copper (Cu), for example, or composed of both a bump and a solder, or the like.

The second electronic component 22 disposed inside the through-hole 10a of the substrate 10 is electrically coupled to a wiring pattern provided on the substrate 10 through the connection member 34, the third electronic component 23, and the connection member 33.

With such a configuration, in the high-frequency module 1, the second electronic component 22 is disposed inside the through-hole 10a of the substrate 10, and a part of the first electronic component 21 and a part of the third electronic component 23 are disposed so as to overlap with the second electronic component 22 in plan view. As a result, compared to a case where the first electronic component 21, the second electronic component 22, and the third electronic component 23 are disposed on the first main surface S1 of the substrate 10, the high-frequency module 1 can be reduced in size in a plane direction.

Since the second electronic component 22 is electrically coupled to the substrate 10 through the connection member 32, the first electronic component 21, and the connection member 31, a bonding wire or the like for supplying the first direct current signal DC1 can be omitted. Therefore, the high-frequency module 1 is capable of achieving reduction in height and material cost.

Since the second electronic component 22 is disposed inside the through-hole 10a of the substrate 10, for example, compared to a configuration in which the second electronic component 22 is embedded in the substrate 10, restrictions on a thickness of the substrate 10 can be reduced. That is, in FIG. 2, the thickness of the substrate 10 is equal to the thickness of the second electronic component 22, but is not limited thereto. The substrate 10 may be thicker than the second electronic component 22, or may be thinner than the second electronic component 22.

Note that when the thickness of the second electronic component 22 is different from the thickness of the substrate 10, an upper surface of the second electronic component 22 may be disposed on the same plane as the first main surface S1 of the substrate 10. As a result, the second electronic component 22 and the first electronic component 21, and the second electronic component 22 and the third electronic component 23 are satisfactorily connected to each other with the connection members 31, 32, 33, and 34 interposed therebetween.

Note that the second electronic component 22 is disposed with a slight gap against an inner peripheral surface of the through-hole 10a of the substrate 10. However, the configuration is not limited thereto, and the second electronic component 22 may be in contact with the inner peripheral surface of the through-hole 10a of the substrate 10. In addition, although not illustrated, the high-frequency module 1 may have a mold resin that seals the first electronic component 21, the second electronic component 22, and the third electronic component 23. In this case, the gap between the second electronic component 22 and the inner peripheral surface of the through-hole 10a of the substrate 10, and the gaps between the first electronic component 21 and the third electronic component 23, and the first main surface S1 of the substrate 10 are also filled with resin.

### (First Modification of First Embodiment)

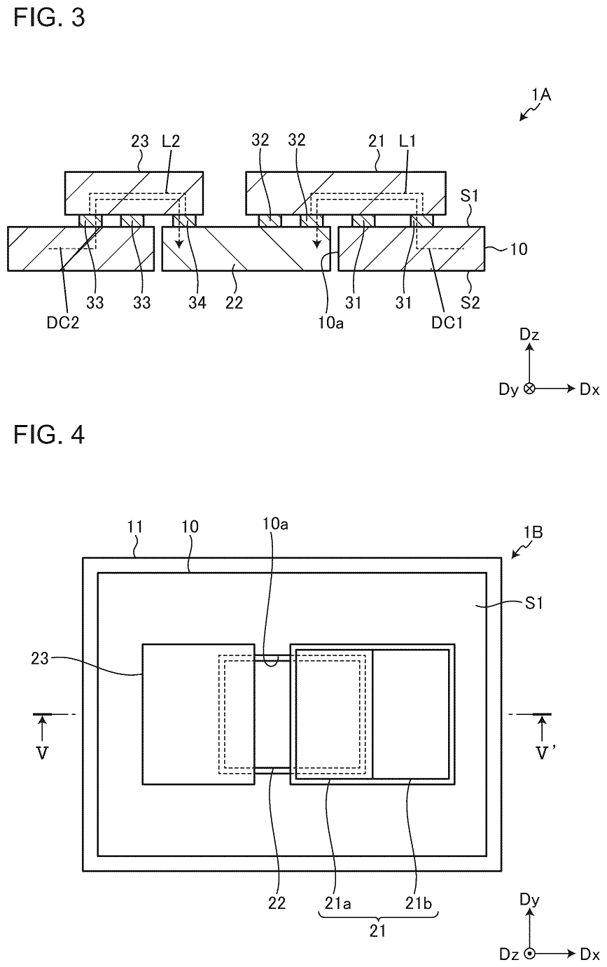

FIG. 3 is a sectional view schematically illustrating a configuration of a high-frequency module according to a first modification of the first embodiment. As illustrated in FIG. 3, in a high-frequency module 1A according to the first modification, the third electronic component 23 is provided with a signal path L2 connecting the connection member 33 and the connection member 34. Note that in FIG. 2, only one signal path L2 is illustrated to facilitate visualization, but a plurality of the signal paths L2 may be formed in the third electronic component 23.

With such a configuration, the second electronic component 22 disposed inside the through-hole 10a of the substrate 10 is electrically coupled to a wiring pattern provided on the substrate 10 through the connection member 34, the third electronic component 23, and the connection member 33. In addition, a second direct current signal DC2 is supplied to the second electronic component 22 from the substrate 10 through the connection member 33 (the third connection member), the signal path L2 of the third electronic component 23, and the connection member 34 (the fourth connection member).

The second direct current signal DC2 is a signal different from the first direct current signal DC1. For example, one of the first direct current signal DC1 and the second direct current signal DC2 may be a ground signal, and another one of the first direct current signal DC1 and the second direct current signal DC2 may be a control signal, a power signal, or the like of the second electronic component 22.

In the high-frequency module 1A according to the first modification, even when a plurality of signals (the first direct current signals DC1 and the second direct current signals DC2) is supplied to the second electronic component 22, a member such as a bonding wire can be omitted.

### Second Embodiment

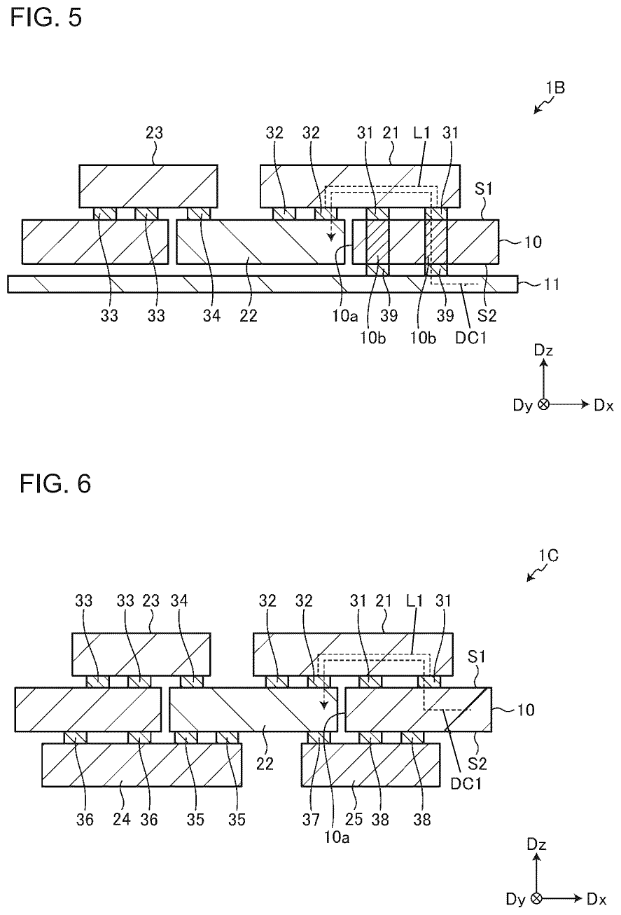

FIG. 4 is a plan view schematically illustrating a configuration of a high-frequency module according to a second embodiment. FIG. 5 is a sectional view taken along line V-V′ of FIG. 4. Compared to the first embodiment and the first modification described above, a high-frequency module 1B according to the second embodiment has a different configuration having a mounting substrate 11.

As illustrated in FIGS. 4 and 5, on the mounting substrate 11, the substrate 10, to which the first electronic component 21, the second electronic component 22, and the third electronic component 23 are connected, is mounted. Specifically, the mounting substrate 11 is disposed so as to face the second main surface S2 of the substrate 10. In the third direction Dz, the substrate 10 and the second electronic component 22 are provided between the mounting substrate 11, and the first electronic component 21 and the third electronic component 23.

As with the substrate 10, the mounting substrate 11 is, for example, a printed circuit board of glass epoxy or the like, a ceramic substrate such as an alumina substrate, a flexible substrate of polyimide or the like, or a liquid crystal polymer substrate. Note that the mounting substrate 11 may be a single-layer substrate or a multilayer substrate. The substrate 10 has a micro wiring pattern suitable to connection with the first electronic component 21 and the third electronic component 23. On the other hand, the mounting substrate 11 need only have a wiring pattern that can be connected to the substrate 10 and has, for example, a wiring pattern having a larger arrangement pitch than that of the substrate 10.

The substrate 10 has a plurality of through-vias 10b provided from the first main surface S1 to the second main surface S2 in the third direction Dz. The plurality of through-vias 10b is provided in a portion of the substrate 10 overlapping with the first electronic component 21. An end portion of each through-via 10b on the first main surface S1 side is electrically coupled to the first electronic component 21 through the connection member 31. An end portion of each through-via 10b on the second main surface S2 side is electrically coupled to the mounting substrate 11 through a mounting terminal 39. That is, a portion of the first electronic component 21 overlapping with the first main surface S1 of the substrate 10 is connected to the mounting substrate 11 with the plurality of through-vias 10b provided in the substrate 10 interposed therebetween. The plurality of through-vias 10b is formed of a conductive material such as silver (Ag), copper (Cu), or the like, for example, and has a higher thermal conductivity than that of a material constituting the substrate 10. Note that in FIG. 5, the plurality of through-vias 10b is provided, but at least one through-via 10b need only be provided.

Here, as illustrated in FIG. 4, the first electronic component 21 has a driver-stage amplifier 21a and a power-stage amplifier 21b. The driver-stage amplifier 21a is a high-frequency power amplifier that amplifies an input high-frequency signal and outputs a first amplified signal. In addition, the power-stage amplifier 21b is a high-frequency power amplifier that further amplifies the first amplified signal outputted from the driver-stage amplifier and output a second amplified signal. The input to the power-stage amplifier 21b is connected to the output from the driver-stage amplifier 21a, and the driver-stage amplifier 21a and the power-stage amplifier 21b constitute a multi-stage amplifier circuit. In the present embodiment, the driver-stage amplifier 21a and the power-stage amplifier 21b are arranged side by side in the first direction Dx. The amount of heat generation in the first electronic component 21 is not constant, and distribution occurs depending on the circuit configuration. For example, the amount of heat generation in the power-stage amplifier 21b is larger than the amount of heat generation in the driver-stage amplifier 21a.

In the present embodiment, the driver-stage amplifier 21a is provided in a portion of the first electronic component 21 overlapping with the second electronic component 22, and the power-stage amplifier 21b is provided in the portion of the first electronic component 21 overlapping with the first main surface S1 of the substrate 10. In this manner, the driver-stage amplifier 21a in which the amount of heat generation is small is disposed so as to overlap with the second electronic component 22, and the power-stage amplifier 21b in which the amount of heat generation is large is disposed so as to overlap with the plurality of through-vias 10b of the substrate 10.

Therefore, compared to a case where the power-stage amplifier 21b is disposed so as to overlap with the second electronic component 22, the heat transmitted from the driver-stage amplifier 21a to the second electronic component 22 is suppressed. In addition, in the present embodiment, the plurality of through-vias 10b functions as a heat transfer path, and the heat generated in the power-stage amplifier 21b of the first electronic component 21 is transmitted to the mounting substrate 11 through the plurality of through-vias 10b of the substrate 10 and is efficiently dissipated to the outside. As a result, the high-frequency module 1B of the present embodiment can improve heat dissipation. Note that the multi-stage amplifier circuit included in the first electronic component 21 may have three or more amplifiers. Here, among the three or more amplifiers, the amplifier disposed on the most output side is a power-stage amplifier, and the other two or more amplifiers are driver-stage amplifiers. In this case, at least the amplifier (driver-stage amplifier) disposed on the most input side may be provided in the portion of the first electronic component 21 overlapping with the second electronic component 22, and the amplifier (power-stage amplifier) disposed on the most output side may be provided in the portion of the first electronic component 21 overlapping with the first main surface S1 of the substrate 10. In other words, amplifiers (other driver-stage amplifiers) disposed between the amplifier on the most input side and the amplifier on the most output side may be disposed in either the portion of the first electronic component 21 overlapping with the second electronic component 22 or the portion of the first electronic component 21 overlapping with the first main surface S1 of the substrate 10.

In addition, in the present embodiment, the first direct current signal DC1 is supplied to the second electronic component 22 from the mounting substrate 11 through the mounting terminal 39, a corresponding one of the through-vias 10b of the substrate 10, the connection member 31 (the first connection member), the signal path L1 of the first electronic component 21, and the connection member 32 (the second connection member).

Note that the high-frequency module 1B of the second embodiment can be combined with the above-described first modification. That is, in FIG. 5, the second direct current signal DC2 may be supplied from the substrate 10 to the second electronic component 22 through the connection member 33, the signal path L2 (see FIG. 3) of the third electronic component 23, and the connection member 34. Alternatively, the plurality of through-vias 10b may also be provided in a portion of the substrate 10 overlapping with the third electronic component 23, and in this case, the second direct current signal DC2 may be supplied from the mounting substrate 11 to the second electronic component 22 through a corresponding one of the through-vias 10b and the third electronic component 23.

### Third Embodiment

FIG. 6 is a sectional view schematically illustrating a configuration of a high-frequency module according to a third embodiment. As illustrated in FIG. 6, in the third embodiment, a configuration in which a high-frequency module 1C has a fourth electronic component 24 and a fifth electronic component 25, in addition to the first electronic component 21, the second electronic component 22, and the third electronic component 23, will be described.

The second main surface S2 of the substrate 10 is provided with the fourth electronic component 24 and the fifth electronic component 25. That is, in the third direction Dz, the substrate 10 and the second electronic component 22 are disposed between the fourth electronic component 24 and the fifth electronic component 25, and the first electronic component 21 and the third electronic component 23. The fourth electronic component 24 and the fifth electronic component 25 are active components. Specifically, the fourth electronic component 24 is, for example, a low-noise amplifier, and the fifth electronic component 25 is, for example, a switch circuit. The fourth electronic component 24 and the fifth electronic component 25 are configured as IC chips.

The fourth electronic component 24 is disposed so as to extend over the second main surface S2 of the substrate 10 and the second electronic component 22. In other words, the fourth electronic component 24 has a portion overlapping with the second electronic component 22 and a portion overlapping with the second main surface S2 of the substrate 10 in plan view. The fourth electronic component 24 faces the third electronic component 23 with the substrate 10 and the second electronic component 22 interposed therebetween.

The fifth electronic component 25 is disposed so as to be adjacent to the fourth electronic component 24 with a space interposed therebetween in the first direction Dx. The fifth electronic component 25 is disposed so as to extend over the second main surface S2 of the substrate 10 and the second electronic component 22. In other words, the fifth electronic component 25 has a portion overlapping with the second electronic component 22 and a portion overlapping with the second main surface S2 of the substrate 10 in plan view. The fifth electronic component 25 faces the first electronic component 21 with the substrate 10 and the second electronic component 22 interposed therebetween. A part of the fourth electronic component 24 and a part of the fifth electronic component 25 are disposed so as to overlap with the second electronic component 22 in plan view.

As illustrated in FIG. 6, the fourth electronic component 24 is connected to the second electronic component 22 with a connection member 35 (a fifth connection member) interposed therebetween. The connection member 35 is disposed between the second electronic component 22 and the fourth electronic component 24. In addition, the fourth electronic component 24 is connected to the second main surface S2 of the substrate 10 with a connection member 36 (a sixth connection member) interposed therebetween. The connection member 36 is disposed between the second main surface S2 of the substrate 10 and the fourth electronic component 24. With such a configuration, the fourth electronic component 24 is electrically coupled to the third electronic component 23 on the first main surface S1 side through the connection member 35, the second electronic component 22, and the connection member 34.

Similarly, the fifth electronic component 25 is connected to the second electronic component 22 with a connection member 37 (a seventh connection member) interposed therebetween. The connection member 37 is disposed between the second electronic component 22 and the fifth electronic component 25. In addition, the fifth electronic component 25 is connected to the second main surface S2 of the substrate 10 with a connection member 38 (an eighth connection member) interposed therebetween. The connection member 38 is disposed between the second main surface S2 of the substrate 10 and the fifth electronic component 25. With such a configuration, the fifth electronic component 25 is electrically coupled to the first electronic component 21 on the first main surface S1 side through the connection member 37, the second electronic component 22, and the connection member 32. The connection members 35, 36, 37, and 38 are bumps formed of a conductive material such as gold (Au) or copper (Cu), for example.

In the high-frequency module 1C of the present embodiment, the substrate 10 is provided with five electronic components from the first electronic component 21 to the fifth electronic component 25 that are integrated. Specifically, the first electronic component 21 and the third electronic component 23 are disposed on the first main surface S1 side of the substrate 10, the second electronic component 22 is disposed in the through-hole 10a of the substrate 10, and the fourth electronic component 24 and the fifth electronic component 25 are disposed on the second main surface S2 side of the substrate 10. As a result, compared to a case where the electronic components from the first electronic component 21 to the fifth electronic component 25 are disposed on the same plane of the substrate 10, reduction in size in the plane direction can be achieved.

In addition, in the present embodiment, a degree of freedom of signal paths between the respective electronic components can be improved. For example, the fourth electronic component 24 may transmit and receive a signal to and from the third electronic component 23 through the connection member 35, the second electronic component 22, and the connection member 34. Alternatively, the fourth electronic component 24 may transmit and receive a signal to and from the first electronic component 21 through the connection member 35, the second electronic component 22, and the connection member 32. Similarly, the fifth electronic component 25 may transmit and receive a signal to and from the first electronic component 21 or the third electronic component 23 through the second electronic component 22. When transmission and reception of a signal between the first electronic component 21 and the third electronic component 23 disposed on the first main surface S1 and the fourth electronic component 24 and the fifth electronic component 25 disposed on the second main surface S2 through the second electronic component 22 disposed in the through-hole 10a, the signal can be transmitted and received through a wiring line, whose film thickness is likely to be less than that of a through-via extending through the substrate 10, provided in the second electronic component 22. Therefore, the height of the high-frequency module 1C can be further reduced.

### (Second Modification of Third Embodiment)

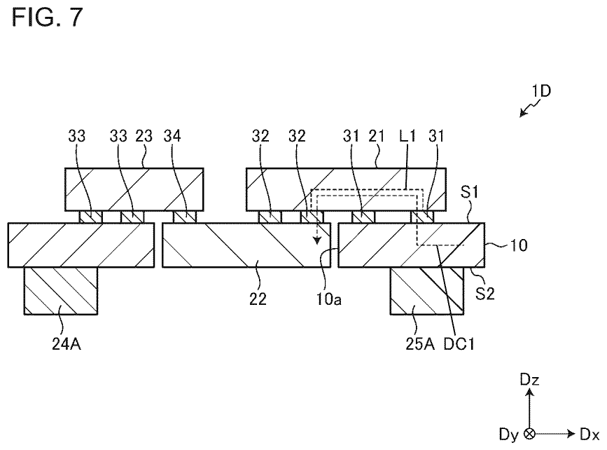

FIG. 7 is a sectional view schematically illustrating a configuration of a high-frequency module according to a second modification of the third embodiment. In the above-described third embodiment, an example in which the fourth electronic component 24 and the fifth electronic component 25 are configured by active components is described, but the configuration is not limited thereto. In a high-frequency module 1D according to the second modification, a fourth electronic component 24A and a fifth electronic component 25A are passive components. Specifically, the fourth electronic component 24A and the fifth electronic component 25A are filter circuits each including a surface mount device such as a capacitor, an inductor, or the like.

Each of the fourth electronic component 24A and the fifth electronic component 25A is provided on the second main surface S2 of the substrate 10 and is not provided in a region overlapping with the second electronic component 22. The fourth electronic component 24A faces the third electronic component 23 with the substrate 10 interposed therebetween. The fifth electronic component 25A faces the first electronic component 21 with the substrate 10 interposed therebetween.

The first electronic component 21 and the third electronic component 23, which are active components, are disposed on the first main surface S1 side of the substrate 10. The second electronic component 22, which is an active component, is disposed in the through-hole 10a of the substrate 10. In addition, the fourth electronic component 24A and the fifth electronic component 25A, which are passive components, are disposed on the second main surface S2 side of the substrate 10. As a result, in the second modification, as with the above-described third embodiment, a plurality of electronic components is integrated and disposed, and thus reduction in size in the plane direction can be achieved.

Note that the high-frequency module 1D according to the second modification is not limited to having a configuration in which both of the fourth electronic component 24A and the fifth electronic component 25A are passive components. One of the fourth electronic component 24A and the fifth electronic component 25A may be a passive component, and another may be an active component. The third embodiment and the second modification can be combined with the above-described first modification.

The above-described embodiments and modifications are only illustrative and can be appropriately changed. For example, two electronic components (the first electronic component 21 and the third electronic component 23) are provided on the first main surface S1 side of the substrate 10, but the configuration is not limited thereto, and one electronic component may be provided on the first main surface S1 side of the substrate 10, or three or more electronic components may be provided. Similarly, one electronic component may be provided on the second main surface S2 side of the substrate 10, or three or more electronic components may be provided. In addition, a thickness and a shape of each electronic component in plan view are only schematically illustrated and can be appropriately changed. In addition, in the above-described embodiments and modifications, a configuration in which the first direct current signal DC1 is supplied to the second electronic component 22 from the substrate 10 through the connection member 31, the first electronic component 21, and the connection member 32 is illustrated, but in addition to this configuration, another direct current signal may be supplied from the second electronic component 22 to the first electronic component 21. Specifically, a ground signal, a power signal, or the like may be further supplied to the first electronic component 21 through the second electronic component 22 and the connection member 32.

Note that the above-described embodiments are intended to facilitate understanding of the present disclosure and are not intended to be construed as limiting the present disclosure. The present disclosure can be modified or improved without departing from the spirit of the present disclosure, and equivalents thereof are also included in the present disclosure.
1, 1A, 1B, 1C, 1D high-frequency module
10 substrate
10a through-hole
10b through-via
11 mounting substrate
21 first electronic component
21a driver-stage amplifier
21b power-stage amplifier
22 second electronic component
23 third electronic component
24, 24A fourth electronic component
25, 25A fifth electronic component
31, 32, 33, 34, 35, 36, 37, 38 connection member
39 mounting terminal
L1, L2 signal path
DC1 first direct current signal
DC2 second direct current signal
S1 first main surface
S2 second main surface

1. A high-frequency module comprising:
a substrate having a first main surface and a second main surface facing each other and a through-hole extending through the substrate from the first main surface to the second main surface;
a first electronic component; and
a second electronic component, wherein
the second electronic component is disposed inside the through-hole of the substrate,
the first electronic component is disposed to extend over the first main surface of the substrate and the second electronic component,
the first electronic component is connected to the first main surface of the substrate with a first connection member interposed therebetween,
the second electronic component is connected to the first electronic component with a second connection member interposed therebetween, and
the high-frequency module is configured to supply a first direct current signal to the second electronic component through the first connection member, the first electronic component, and the second connection member.

2. The high-frequency module according to claim 1, further comprising:
a third electronic component disposed to extend over the first main surface of the substrate and the second electronic component and adjacent to the first electronic component with a space interposed therebetween, wherein
the third electronic component is connected to the first main surface of the substrate with a third connection member interposed therebetween,
the second electronic component is connected to the third electronic component with a fourth connection member interposed therebetween, and
the high-frequency module is configured to supply a second direct current signal to the second electronic component through the third connection member, the third electronic component, and the fourth connection member.

3. The high-frequency module according to claim 1, further comprising:
a mounting substrate facing the second main surface of the substrate, wherein
the first electronic component has a portion overlapping with the second electronic component and a portion overlapping with the first main surface of the substrate in plan view, and
the portion of the first electronic component overlapping with the first main surface of the substrate is connected to the mounting substrate with a through-via interposed therebetween.

4. The high-frequency module according to claim 3, wherein
the first electronic component has a driver-stage amplifier configured to amplify an input high-frequency signal and output a first amplified signal, and a power-stage amplifier configured to amplify the first amplified signal and output a second amplified signal,
the portion of the first electronic component overlapping with the second electronic component is provided with the driver-stage amplifier, and
the portion of the first electronic component overlapping with the first main surface of the substrate is provided with the power-stage amplifier.

5. The high-frequency module according to claim 2, further comprising:
a fourth electronic component disposed on the second main surface of the substrate.

6. The high-frequency module according to claim 5, wherein
the fourth electronic component is disposed to extend over the second main surface of the substrate and the second electronic component,
the fourth electronic component is connected to the second electronic component with a fifth connection member interposed therebetween, and
the fourth electronic component is connected to the third electronic component with the fifth connection member, the second electronic component, and the fourth connection member interposed therebetween.

7. The high-frequency module according to claim 2, further comprising:
a mounting substrate facing the second main surface of the substrate, wherein
the first electronic component has a portion overlapping with the second electronic component and a portion overlapping with the first main surface of the substrate in plan view, and
the portion of the first electronic component overlapping with the first main surface of the substrate is connected to the mounting substrate with a through-via interposed therebetween.
